(19) United States
(12) Patent Application Publication
(10) Pub. No.: US 2025/0248317 A1
(43) Pub. Date: Jul. 31, 2025

(54) Dopants to Increase BiSbX Bandgap for Optimal CPP Conductivity

(71) Applicant: Western Digital Technologies, Inc., San Jose, CA (US)

(72) Inventors: Quang LE, San Jose, CA (US); Brian R. YORK, San Jose, CA (US); Michael A. GRIBELYUK, Stamford, CT (US); Jason S. JAMES, San Jose, CA (US); Hisashi TAKANO, Fujisawa-shi, Kanagawa (JP); Xiaoyong LIU, San Jose, CA (US); Son T. LE, San Jose, CA (US); Hassan OSMAN, San Jose, CA (US); Maki MAEDA, Fujisawa-shi, Kanagawa (JP)

(73) Assignee: Western Digital Technologies, Inc., San Jose, CA (US)

(21) Appl. No.: 19/011,149

(22) Filed: Jan. 6, 2025

Related U.S. Application Data
(60) Provisional application No. 63/676,739, filed on Jul. 29, 2024.
(60) Provisional application No. 63/625,767, filed on Jan. 26, 2024.

(51) Int. Cl. H10N 50/85; G11B 5/39; H10N 50/10; H10N 52/80

(52) U.S. Cl. CPC H10N 50/85; G11B 5/3909; H10N 50/10; H10N 52/80

(57) ABSTRACT

Current-perpendicular-to-plane (CPP) spin orbit torque (SOT) devices generally require a lower bulk conductivity to minimize shunting while maintaining a high spin Hall angle and strong thermal stability. A CPP SOT device comprises a ferromagnetic layer and a topological insulating (TI) layer comprising one of: BiSb doped with Ge and MgTiO; C; Z; ZTiO; or ZO, where Z is one of Mg, Be, Ca, Sr, or Ba. Doping the TI layer comprising BiSb decreases the bulk conductivity of the TI layer while increasing the melting temperature of the TI layer. The TI layer has a thickness between about 50 Å to about 600 Å, a conductivity between about 0.2×10⁵ ohm⁻¹ m⁻¹ to about 1.1×10⁵ ohm⁻¹ m⁻¹, and a melting point between about 293° C. to about 302° C. The CPP SOT device may further comprise a buffer layer, a first interlayer, a second interlayer, and a cap layer.

### CROSS-REFERENCE TO RELATED APPLICATIONS

This application claims benefit of U.S. provisional patent application Ser. Nos. 63/625,767, filed Jan. 26, 2024, and 63/676,739, filed Jul. 29, 2024, each of which is herein incorporated by reference.

### BACKGROUND OF THE DISCLOSURE

### Field of the Disclosure

Embodiments of the present disclosure generally relate to topological insulator (TI) based spin-orbit torque devices and a method of forming thereof.

### Description of the Related Art

BiSb layers are narrow band gap topological insulators with both giant spin Hall effect and high electrical conductivity. BiSb is a material that has been proposed in various spin-orbit torque (SOT) device applications, such as for a spin Hall layer for magnetoresistive random access memory (MRAM) devices and energy-assisted magnetic recording (EAMR) write heads and high linear resolution read heads.

However, utilizing BiSb materials in commercial SOT applications can present several obstacles. For example, BiSb materials have low melting points, large grain sizes, significant Sb migration issues upon thermal annealing due to its film roughness, difficulty in maintaining a desired (012) or (001) orientation for maximum spin Hall effect, and are generally soft and easily damaged by ion milling. Furthermore, the requirements of the properties of the BiSb layer vary depending on the type of SOT device. For example, devices where current flows current-in-plane (CIP) have different property requirements than devices where current flows current-perpendicular-plane (CPP).

Therefore, there is a need for improved BiSb layers having various desired properties tailored to specific SOT devices.

### SUMMARY OF THE DISCLOSURE

Current-perpendicular-to-plane (CPP) spin orbit torque (SOT) devices generally require a lower bulk conductivity to minimize signal shunting while maintaining a high spin Hall angle and strong thermal stability. A CPP SOT device comprises a ferromagnetic layer and a topological insulating (TI) layer comprising one of: one of: BiSb doped with Ge and MgTiO; BiSb doped with TiO, Z, ZTiO, or ZO, where Z is one of Mg, Be, Ca, Sr, or Ba; BiSb doped with C; or BiSb doped with an X—C dopant or an X—O dopant, where X is one or more elements selected from the group consisting of: Sc, Ti, V, Cr, Mn, Fe, Co, Ni, Cu, Zn, Y, Zr, Nb, Mo, Rh, Ag, Ta, Hf, W, Re, Ir, Pt, B, Al, Ga, In, Si, Ge, Sn, P, As, Se, and Te. Doping the TI layer comprising BiSb with the above-mentioned dopants decreases the bulk conductivity of the TI layer while increasing the melting temperature of the TI layer. The TI layer has a thickness between about 50 Å to about 600 Å, a conductivity between about 0.2×10⁵ ohm⁻¹ m⁻¹ to about 1.1×10⁵ ohm⁻¹ m⁻¹, and a melting point between about 293° C. to about 302° C. The CPP SOT device may further comprise a buffer layer, a first interlayer, a second interlayer, and a cap layer.

In one embodiment, a SOT device comprises a ferromagnetic layer, and a topological insulating (TI) layer comprising one of: BiSb doped with Ge and MgTiO; BiSb doped with TiO, Z, ZTiO, or ZO, where Z is one of Mg, Be, Ca, Sr, or Ba; BiSb doped with FeCrC; BiSb doped with C; or BiSb doped with X—C or X-O, where X is one or more elements selected from the group consisting of: Sc, Ti, V, Cr, Mn, Fe, Co, Ni, Cu, Zn, Y, Zr, Nb, Mo, Rh, Ag, Ta, Hf, W, Re, Ir, Pt, B, Al, Ga, In, Si, Ge, Sn, P, As, Se, and Te.

In another embodiment, a current-perpendicular-to-plane (CPP) SOT device comprises a ferromagnetic layer, and a topological insulating (TI) layer comprising one of: BiSb doped with Ge and MgTiO; BiSb doped with TiO, Z, ZTiO, or ZO, where Z is one of Mg, Be, Ca, Sr, or Ba; BiSb doped with C; or BiSb doped with an X—C dopant or an X—O dopant, where X is one or more elements selected from the group consisting of: Sc, Ti, V, Cr, Mn, Fe, Co, Ni, Cu, Zn, Y, Zr, Nb, Mo, Rh, Ag, Ta, Hf, W, Re, Ir, Pt, B, Al, Ga, In, Si, Ge, Sn, P, As, Se, and Te, wherein the TI layer has a thickness between about 50 Å to about 600 Å.

In yet another embodiment, a current-perpendicular-to-plane (CPP) SOT device comprises a buffer layer, a ferromagnetic layer, a first interlayer, a second interlayer, a cap layer, and a topological insulating (TI) layer comprising one of: BiSb doped with Ge and MgTiO; BiSb doped with TiO, Z, ZTiO, or ZO, where Z is one of Mg, Be, Ca, Sr, or Ba; BiSb doped with C; or BiSb doped with an X—C dopant or an X—O dopant, where X is one or more elements selected from the group consisting of: Sc, Ti, V, Cr, Mn, Fe, Co, Ni, Cu, Zn, Y, Zr, Nb, Mo, Rh, Ag, Ta, Hf, W, Re, Ir, Pt, B, Al, Ga, In, Si, Ge, Sn, P, As, Se, and Te.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic illustration of certain embodiments of a magnetic media drive including a write head having a SOT MTJ device.

FIG. 2 is a fragmented, cross-sectional side view of certain embodiments of a HDD read/write head having a SOT MTJ device.

FIG. 3A illustrates a spin orbit torque (SOT) device, according to one embodiment.

FIG. 3B illustrates a SOT device, according to another embodiment.

FIG. 4 illustrates a current-perpendicular-plane (CPP) SOT device, according to one embodiment.

FIG. 5A illustrates a graph of conductivity (i.e., the inverse of resistivity (ρ) (1/ρ)×1000) of the BiSbX (where X is a dopant) versus thickness of various BiSbX layers in Å, according to one embodiment.

FIG. 5B illustrates a graph of conductivity (i.e., the inverse of resistivity (ρ) (1/ρ)×1000) of the BiSbX (where X is either TiO at 8 at. % or Mg at 5 at. % dopant) versus thickness of BiSbX (where X is either TiO at 8 at. % or Mg at 5 at. % dopant) in Å that reduces the bulk conductivity and increase the bandgap, compared to undoped BiSb according to another embodiment.

FIG. 6 illustrates a graph of heat flow (in Watts/gram) versus temperature in Celsius for various BiSbX layers, according to one embodiment.

FIG. 7 illustrates a graph of iSHE signal (in ohms) coming from TI layers versus the spin Hall angle (SHA), according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

Current-perpendicular-to-plane (CPP) spin orbit torque (SOT) devices generally require a lower bulk conductivity to minimize shunting while maintaining a high spin Hall angle and strong thermal stability. A CPP SOT device comprises a ferromagnetic layer and a topological insulating (TI) layer comprising one of: BiSb doped with Ge and MgTiO or BiSb doped with C, Mg, or TiO. Doping the TI layer comprising BiSb with Ge and MgTiO or BiSb doped with C, Mg, or TiO decreases the bulk conductivity of the TI layer while increasing the melting temperature of the TI layer. The TI layer has a thickness between about 50 Å to about 600 Å, a conductivity between about 0.2×10⁵ ohm⁻¹ m⁻¹ to about 1.1×10⁵ ohm⁻¹ m⁻¹, and a melting point between about 293° C. to about 302° C. The CPP SOT device may further comprise a buffer layer, a first interlayer, a second interlayer, and a cap layer.

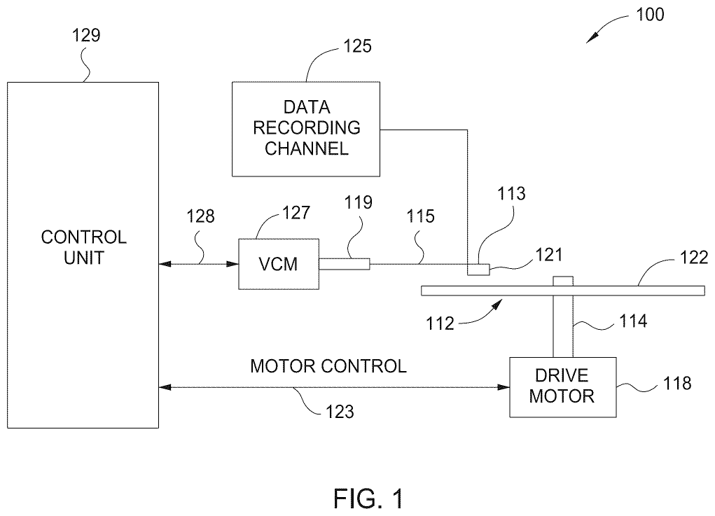

FIG. 1 is a schematic illustration of certain embodiments of a magnetic media drive 100 including a write head having a SOT MTJ device. Such a magnetic media drive may be a single drive or comprise multiple drives. For the sake of illustration, a single disk drive 100 is shown according to certain embodiments. As shown, at least one rotatable magnetic disk 112 is supported on a spindle 114 and rotated by a drive motor 118. The magnetic recording on each magnetic disk 112 is in the form of any suitable patterns of data tracks, such as annular patterns of concentric data tracks (not shown) on the magnetic disk 112.

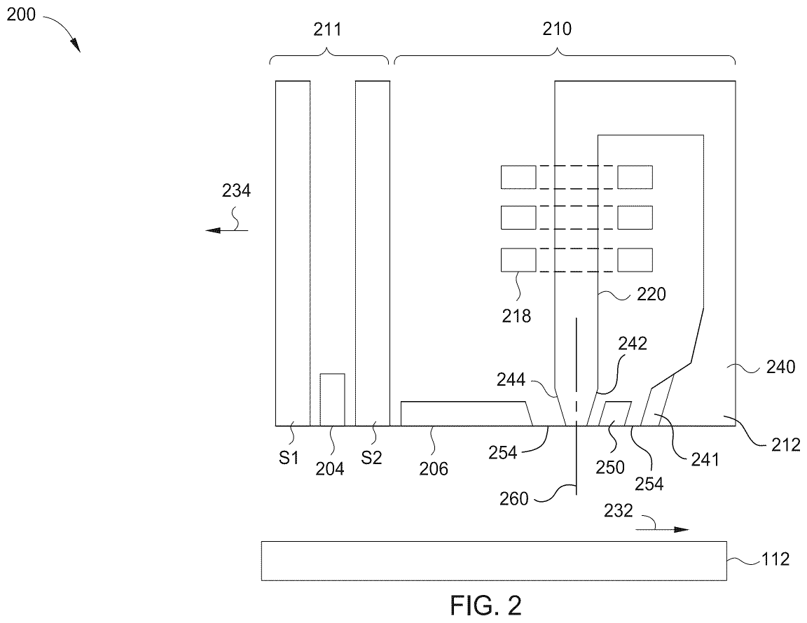

At least one slider 113 is positioned near the magnetic disk 112, each slider 113 supporting one or more magnetic head assemblies 121 that include a SOT device. As the magnetic disk 112 rotates, the slider 113 moves radially in and out over the disk surface 122 so that the magnetic head assembly 121 may access different tracks of the magnetic disk 112 where desired data are written. Each slider 113 is attached to an actuator arm 119 by way of a suspension 115. The suspension 115 provides a slight spring force which biases the slider 113 toward the disk surface 122. Each actuator arm 119 is attached to an actuator means 127. The actuator means 127 as shown in FIG. 2 may be a voice coil motor (VCM). The VCM includes a coil movable within a fixed magnetic field, the direction and speed of the coil movements being controlled by the motor current signals supplied by control unit 129.

During operation of the disk drive 100, the rotation of the magnetic disk 112 generates an air bearing between the slider 113 and the disk surface 122 which exerts an upward force or lift on the slider 113. The air bearing thus counter-balances the slight spring force of suspension 115 and supports slider 113 off and slightly above the disk surface 122 by a small, substantially constant spacing during normal operation.

The various components of the disk drive 100 are controlled in operation by control signals generated by control unit 129, such as access control signals and internal clock signals. Typically, the control unit 129 comprises logic control circuits, storage means and a microprocessor. The control unit 129 generates control signals to control various system operations such as drive motor control signals on line 123 and head position and seek control signals on line 128. The control signals on line 128 provide the desired current profiles to optimally move and position slider 113 to the desired data track on disk 112. Write and read signals are communicated to and from write and read heads on the assembly 121 by way of recording channel 125.

The above description of a typical magnetic media drive and the accompanying illustration of FIG. 1 are for representation purposes only. It should be apparent that magnetic media drives may contain a large number of media, or disks, and actuators, and each actuator may support a number of sliders.

FIG. 2 is a fragmented, cross-sectional side view of certain embodiments of a read/write head 200 having a SOT device. The read/write head 200 faces a magnetic media 112. The read/write head 200 may correspond to the magnetic head assembly 121 described in FIG. 1. The read/write head 200 includes a media facing surface (MFS) 212, such as a gas bearing surface, facing the disk 112, a write head 210, and a magnetic read head 211. As shown in FIG. 2, the magnetic media 112 moves past the write head 210 in the direction indicated by the arrow 232 and the read/write head 200 moves in the direction indicated by the arrow 234.

In some embodiments, the magnetic read head 211 is a magnetoresistive (MR) read head that includes an MR sensing element 204 located between MR shields S1 and S2. In other embodiments, the magnetic read head 211 is a magnetic tunnel junction (MTJ) read head that includes a MTJ sensing device 204 located between MR shields S1 and S2. The magnetic fields of the adjacent magnetized regions in the magnetic disk 112 are detectable by the MR (or MTJ) sensing element 204 as the recorded bits. The SOT device of various embodiments can be incorporated into the read head 211 as the sensing element. An example of an SOT read head is described in co-pending patent application titled “Topological Insulator Based Spin Torque Oscillator Reader,” U.S. application Ser. No. 17/828,226, filed May 31, 2022, assigned to the same assignee of this application, which is herein incorporated by reference.

The write head 210 includes a main pole 220, a leading shield 206, a trailing shield 240, an optional spin orbital torque (SOT) device 250, and a coil 218 that excites the main pole 220. The coil 218 may have a “pancake” structure which winds around a back-contact between the main pole 220 and the trailing shield 240, instead of a “helical” structure shown in FIG. 2. When included, e.g., to achieve a Microwave Assisted Magnetic Recording (MAMR) effect, the SOT device 250 is formed in a gap 254 between the main pole 220 and the trailing shield 240. The main pole 220 includes a trailing taper 242 and a leading taper 244. The trailing taper 242 extends from a location recessed from the MFS 212 to the MFS 212. The leading taper 244 extends from a location recessed from the MFS 212 to the MFS 212. The trailing taper 242 and the leading taper 244 may have the same degree of taper, and the degree of taper is measured with respect to a longitudinal axis 260 of the main pole 220. In some embodiments, the main pole 220 does not include the trailing taper 242 and the leading taper 244. Instead, the main pole 220 includes a trailing side (not shown) and a leading side (not shown), and the trailing side and the leading side are substantially parallel. The main pole 220 may be a magnetic material, such as a FeCo alloy. The leading shield 206 and the trailing shield 240 may be a magnetic material, such as a NiFe alloy. In certain embodiments, the trailing shield 240 can include a trailing shield hot buffer layer 241. The trailing shield hot buffer layer 241 can include a high moment sputter material, such as CoFeN, FeXN, or FeX, where X includes at least one of N, Al, Ni, Co, Ta, Re, Ir, Pt, Rh, Ta, Zr, and Ti. In certain embodiments, the trailing shield 240 does not include a trailing shield hot buffer layer.

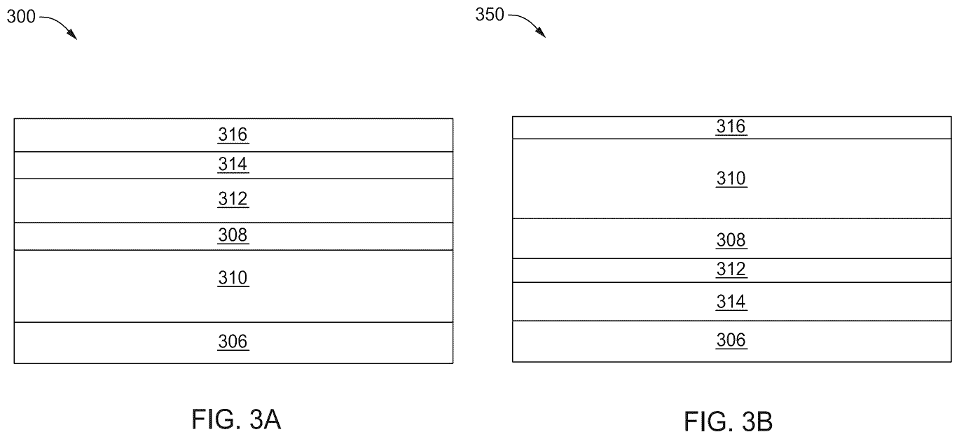

FIG. 3A illustrates a spin orbit torque (SOT) device 300, according to one embodiment. The SOT device 300 comprises a buffer layer 306, which may be disposed over a first shield or substrate (depending on end application, not shown) and/or an insulation layer (not shown), a spin Hall effect (SHE) layer or BiSb layer 310 (which may also be referred to herein as a topological insulator (TI) layer 310 or SOT layer 310) disposed on the buffer layer 306, a first interlayer (interlayer1) 308 disposed on the SHE layer 310, a ferromagnetic (FM) layer 312 disposed on the first interlayer1 308, a second interlayer (interlayer2) 314 disposed on the FM layer 312, and a cap layer 316 disposed on the interlayer2 314. A second shield or substrate (depending on end application, not shown) and/or an insulation layer (not shown) may be disposed over the cap layer 316.

FIG. 3B illustrates a SOT device 350, according to another embodiment. The SOT device 350 comprises a buffer layer 306, which may be disposed over a first shield or substrate (depending on end application, not shown) and/or an insulation layer (not shown), a second interlayer (interlayer2) 314 disposed on the buffer layer 306, a ferromagnetic (FM) layer 312 disposed on the interlayer2 314, a first interlayer (interlayer1) 308 disposed on the FM layer 312, a spin Hall effect (SHE) layer or BiSb layer 310 (which may also be referred to herein as a topological insulator (TI) layer 310) disposed on the interlayer1 308, and a cap layer 316 disposed on the BiSb layer 310. A second shield (not shown) and/or an insulation layer or substrate (depending on end application, not shown) may be disposed over the cap layer 316.

In both SOT devices 300, 350, the TI layer 310 may comprise doped or undoped bismuth antimony (BiSb) of various thicknesses, as discussed further below. In one embodiment, the TI layer 310 comprises undoped BiSb, BiSb doped with Mg, Be, Ca, Sr, Ba, TiO, ZTiO, Z, or ZO, where Z is one of Mg, Be, Ca, Sr, or Ba, or doped BiSbX, where X is less than 8 at. % and extracted from elements which don't readily interact with either Bi or Sb, such as Cu, Ag, Ge, Mg, Ni, Co Mo, W, Sn, B, N, In, Te, Se, Y, Zr, Pt, Ti, or in alloy combinations thereof. In some embodiments, the TI layer is doped with increasing bandgap dopants, such as low atomic number (Z) containing oxides, carbides, or borides, like TiO, VO, C, TIC, VC, or B₄C, B, TiB, Z, ZTiO, or ZO, where Z is one of Mg, Be, Ca, Sr, or Ba, or composite alloys thereof. In some cases where high Z oxide dopants, carbide dopants, or boride dopants which don't significantly affect the TI properties, like WO, WC, or WB, can be also used. In such an embodiment, the amount of oxide, carbide, or boride dopant may be about 8 at. % or less. The dopants and the thickness of the TI layer 310 are selected during fabrication based on the level of bulk conductivity desired. In embodiments where the TI layer 310 is doped, the interlayer1 308, the buffer layer 306, and/or the cap layer 316 may be doped as well. The TI layer 310 may have a (012) crystal orientation or a (001) crystal orientation. The TI layer 310 may have a thickness in the y-direction of about 50 Å to about 600 Å. Note in this disclosure when doping is mentioned, different options for doping can be pursued, including co-sputtering and lamination.

The cap layer 316 may comprise nonmagnetic, high resistivity materials, such as: thin ceramic oxides or nitrides of TiN, SiN, MgTiO, and MgO; amorphous/nanocrystalline metals such as NiFeGe, NiFeTa, NiTa, NiHf, NiFeHf, CoHf, CoFeHf, NiWTa, NiFeW, NiW, wRe; or nitrides, oxides, or borides of above-mentioned elements, compounds, and/or alloys such as NiTaN, NiFeTaN, NiWTaN, NiWN, WReN, TaN, WN, TaOx, WOx, WB, HfB, NiHfB, NiFeHfB, CoHfB, and CoFeHfB, where x is a numeral. In some embodiments, lower atomic number (Z) materials are preferred in the cap layer 316 to reduce sputter intermixing with the FM layer 312, but high Z alloys can be used, if used in combination with a migration barrier beneath, or if the high Z elements are used with a high resistive oxide, nitride, or boride. The cap layer 316 can comprise multilayer combinations of the above-mentioned materials, and the overall thickness of the cap layer 316 is less than or equal to about 100 Å (nominally about 15 Å to about 50 Å).

The FM layer 312, which may serve as a part of the interlayer2 314, has a thickness of about 5 Å to about 15 Å, and may comprise NiFe, CoFe, NiFeX, CoFeX, FeX, or Nix, where X=Cr, Co, Ni, Cu, Si, Al, Mn, Ge, Ta, Hf, W, Re, Pt, Ir, N, and B. The FM layer 312 may comprise any magnetic layer combination or alloy combination of these elements that can yield a low coercivity, negative magnetostrictive FM layer 312 or in multilayer combinations with other higher polarizing materials like Heusler alloys or high Ni containing alloy FM layers. The interlayer2 314 may comprise CoFeB, Co, CoFe, NiFe, or a similar material as the FM layer 312.

The SOT devices 300, 350 may be textured amorphous/nanocrystalline stacks or epitaxial stacks. When the SOT devices 300, 350 are textured amorphous/nanocrystalline stacks, the buffer layer 306 (and/or the seed layer if included) may comprise high resistance nonmagnetic amorphous/nanocrystalline material with nearest-neighbor diffraction peak 2.0 Å to about 2.5 Å or a crystalline or nano-crystalline fcc metal with a (111) texture an a-axis of about 3.5 Å to about 4.0 Å, such as NiX, NiFeX, CoX, CoFeX, and CuX, where, for example, X=Cr, Co, Fe, Cu, Ta, W, Hf, B, N, Ge, Al, Re, Pt, Ir, Zr, Nb, Mo, or alloy combinations thereof. The buffer layer 306 may be a bilayer or a multilayer structure comprising high resistance insulating layers (crystalline or nanocrystalline), for example, NiFeGe/MgO/NiFeGe, CuGe/MgO/NiGe, or other insulators like AlN etc.

When the SOT devices 300, 350 are textured amorphous/nanocrystalline stacks, the interlayer1 308 and the interlayer2 314 may each individually comprise a single layer or a multilayer structure of high resistance nonmagnetic amorphous/nanocrystalline material with nearest-neighbor diffraction peak from 2.0 Å to about 2.5 Å a crystalline or nano-crystalline fcc metal with a (111) texture an a-axis of about 3.5 Å to about 4.0 Å, such as NiX, NiFeX, CoX, CoFeX, and CuX, where, for example, X=Cr, Co, Fe, Cu, Ta, W, Hf, B, N, Ge, Al, Re, Pt, Ir, Zr, Nb, Mo, or alloy combinations thereof, or a multilayer structure comprising a high polarizing layer next to the FM layer 312, or a high resistance spin diffusing insulating layer, such as MgO or NiO.

When the SOT devices 300, 350 are epitaxial stacks, the seed layer or substrate layer may comprise high resistance nonmagnetic amorphous/nanocrystalline material with nearest-neighbor diffraction peak 2.0 Å to about 2.5 Å a crystalline or nano-crystalline fcc metal with a (111) texture an a-axis of about 3.5 Å to about 4.0 Å, such as NiX, NiFeX, Cox, CoFeX, and CuX, where, for example, X=Cr, Co, Fe, Cu, Ta, W, Hf, B, N, Ge, Al, Re, Pt, Ir, Zr, Nb, Mo, or alloy combinations thereof. The buffer layer 306 may comprise a (100) textured layer (not shown) deposited on a heated substrate or seed layer, the textured layer which maybe heated comprising a layer or multilayers of Al-X where X=Fe, Co, Ni, Ru, Rh, Ir or texture layer of heated Cr>250 C or heated Cr—X alloys where X=Mo, Mn, Ru, Ti, and W.

When the SOT devices 300, 350 are epitaxial stacks, the buffer layer 306 may comprise (1) high resistance crystalline fcc materials like MgO, TiO, and VO, (2) nitrides and carbides of Sc, Ti, V, Cr, Zr, Nb, Ta, Hf, and W, (3) B2 or bcc materials like NiAl, RuAl, RhAl, etc., or (4) X-Al binary alloys, where X=Fe, Co, Ni, Ru, Rh, Ir, etc. The interlayer1 308 may be a single layer or a multilayer structure comprising a high resistance layer like that in the buffer layer 306 in combination with a high spin polarizing layer magnetic or non-magnetic Heusler alloy or half Heusler alloy. Examples of high spin polarizing layer magnetic or non-magnetic Heusler alloys or half Heusler alloys may be found in co-pending patent application titled “Spin-Orbit Torque Reader with Recessed Spin Hall Effect Layer,” U.S. application Ser. No. 18/368,220, filed Sep. 14, 2023, assigned to the same assignee of this application, which is herein incorporated by reference. The interlayer2 314 may be a single layer or a multilayer structure comprising a crystalline high resistance layer like that in the buffer layer 306 in combination with any other high resistance layer, such as a crystalline or amorphous/nanocrystalline layer like AlN or SiN, or any high resistance amorphous layer like NiFeGe.

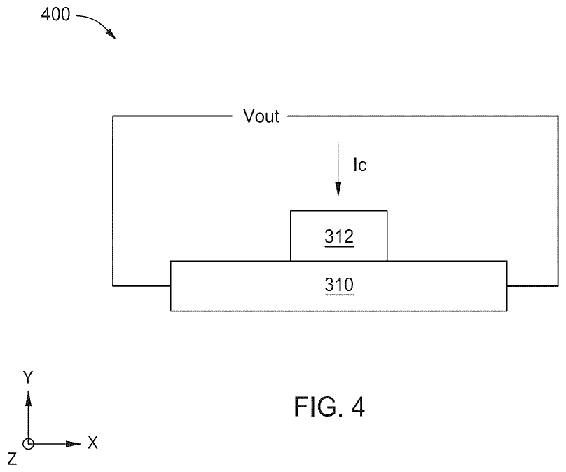

FIG. 4 illustrates a current-perpendicular-plane (CPP) SOT device 400, according to one embodiment. The CPP SOT device 400 may be used in combination with the SOT device 300 of FIG. 3A and/or the SOT device 350 of FIG. 3B. The SOT device 400 comprises a TI layer 310 and the FM layer 312 disposed over the TI layer 310. While the FM layer 312 is disposed over the TI layer 310, the TI layer 310 may be disposed over the FM layer 312 instead. The SOT device 400 may comprise additional layers not shown, such as a buffer layer 306, an interlayer1 308, an interlayer2 314, and/or a cap layer 316, as discussed above.

During operation, current (Ic) is applied to the top of the FM layer 312 in the y-direction, or perpendicular to the plane of the TI layer 310. A spin current is generated and flows perpendicularly towards the SOT layer 310, and due to the inverse spin Hall effect, there will be a charge potential difference and hence the voltage read out (Vout) along x-direction. Such CPP SOT devices 400 generally require the bulk conductivity property of the TI layer 310 to be lower and more insulating to minimize shunting during signal read out. For example, the CPP SOT device 400 may be used in read heads, such as the read head 211 of FIG. 2.

As mentioned above, in the SOT device 400, the TI layer 310 may comprise doped or undoped bismuth antimony (BiSb) of various thicknesses, as discussed further below. In one embodiment, the TI layer 310 comprises BiSbGe doped with MgTiO, or BiSb doped with Mg or TiO. In such an embodiment comprising BiSbGe, the amount of Ge may be about 5 at. % or less and the amount of MgTiO may be about 8 at. % or less. The amount of dopant, including C, X—C, or X—O dopants, in the TI layer 310 may be less than about 8 at. %, such as about 0.5 at. % to about 8 at. %. The TI layer 310 may have a (012) crystal orientation or a (001) crystal orientation. The TI layer 310 may have a thickness in the y-direction of about 50 Å to about 600 Å, such as about 150 Å to about 600 Å. As such, the TI layer 310 may be referred to herein as a BiSb layer 310. The dopants and the thickness of the BiSb layer 310 are selected during fabrication based on the level of bulk conductivity desired. In the CPP SOT device 400, the amount of conductivity selected is about 1.0×10⁵ ohm⁻¹ m⁻¹ or below.

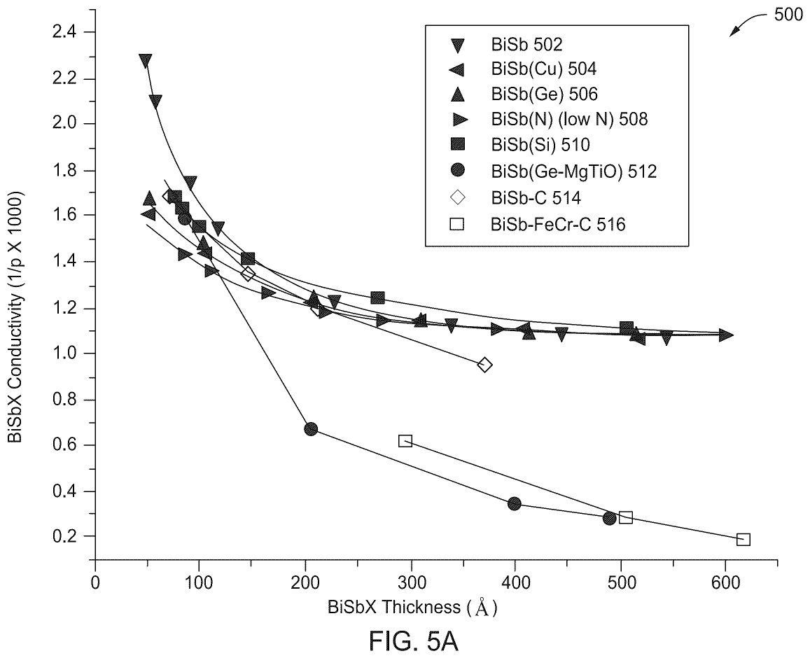

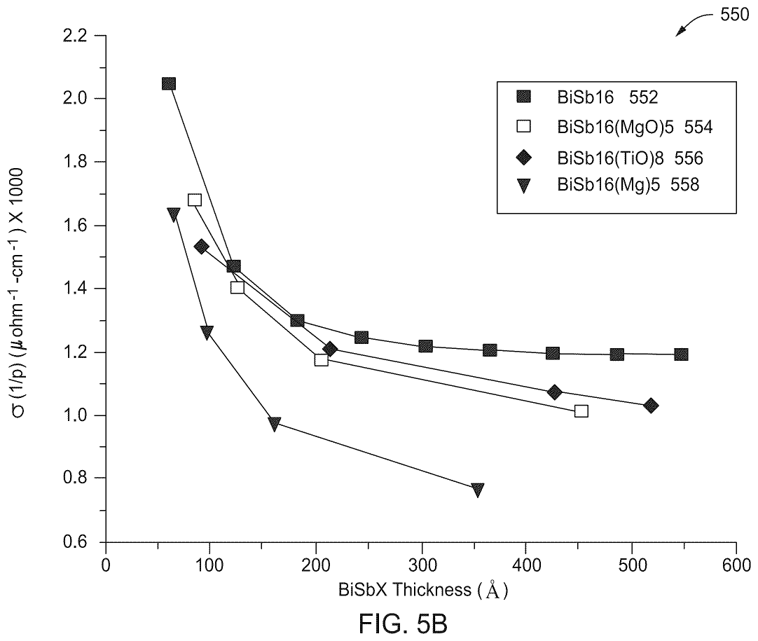

FIG. 5A illustrates a graph 500 of total film conductivity (i.e., the inverse of resistivity (ρ) (1/ρ)×1000, or in units of ohm⁻¹ m⁻¹) of the BiSbX comprising 10% of Sb (where X is a dopant) versus thickness of various BiSbX layers in Å, according to one embodiment. FIG. 5B illustrates a graph 550 of conductivity (i.e., the inverse of resistivity (ρ) (1/ρ)×1000) of the BiSbX comprising 16% of Sb (where X is either TiO at 8 at. % or Mg at 5 at. % dopant) versus thickness of BiSbX (where X is either TiO at 8 at. % or Mg at 5 at. % dopant) in Å that reduces the bulk conductivity and increase the bandgap, compared to undoped BiSb according to another embodiment. Each of the various BiSbX layers may be the BiSb layer 310 of any of the SOT devices 300, 350, 400 of FIGS. 3A-4.

In the graph 500 of FIG. 5A, line 502 represents undoped BiSb, line 504 represents BiSbCu, line 506 represents BiSbGe, line 508 represents BiSbN doped with N₂, where N doping amount is small (less than about 4 at. %), line 510 represents BiSbSi, line 512 represents BiSb (Ge—MgTiO), line 514 represents BiSbC, and line 516 represents BiSb(FeCr—C). In FIG. 5B, line 552 represents undoped BiSb with about 16 at. % Sb, line 554 represents BiSb with about 16 at. % Sb that is doped with about 5 at. % of MgO, line 556 represents BiSb with about 16 at. % Sb that is doped with about 8 at. % of TiO, and line 558 represents BiSb with about 16 at. % Sb that is doped with about 5 at. % of Mg. The amount of dopant in each BiSbX layer may be generally less than about 10 at. %. The BiSbX layer may have a (012) crystal orientation or a (001) crystal orientation. The BiSbX layer may have a thickness in the y-direction of about 50 Å to about 600 Å.

The bulk conductivity of the BiSbX layers can vary depending on increasing or decreasing the band gap energy of the BiSbX layers while maintaining the similar high TI surface conductivity. For example, oxides having a low atomic number (Z) have a higher band gap, and thus, a lower conductivity. As shown in the graph 500 by line 512, BiSb doped with Ge—MgTiO significantly reduces the conductivity of the BiSb or TI layer to about 0.2×10⁵ ohm⁻¹ m⁻¹ to about 1.1×10⁵ ohm⁻¹ m⁻¹. At thicknesses of about 150 Å or greater, the bulk conductivity is reduced even further, such as about 0.2×10⁵ ohm⁻¹ m⁻¹ to about 0.6×10⁵ ohm⁻¹ m⁻¹. Furthermore, line 514, BiSb doped with C, and line 516, BiSb doped with FeCr—C, both significantly reduce the conductivity as well, to about 0.1 ohm⁻¹ m⁻¹ to about 0.7 ohm⁻¹ m⁻¹. In BiSb doped with Ge and MgTiO, the MgTiO looks to interact with Ge rather than the BiSb. As such, MgTiO is unreactive with BiSb, resulting in a very smooth BiSbGeMgTiO layer, even at large thicknesses of 500 Å or higher. Furthermore, in FIG. 5B, BiSb16 at. % doped with 5 at. % Mg or 8 at. % TiO significantly reduces the conductivity.

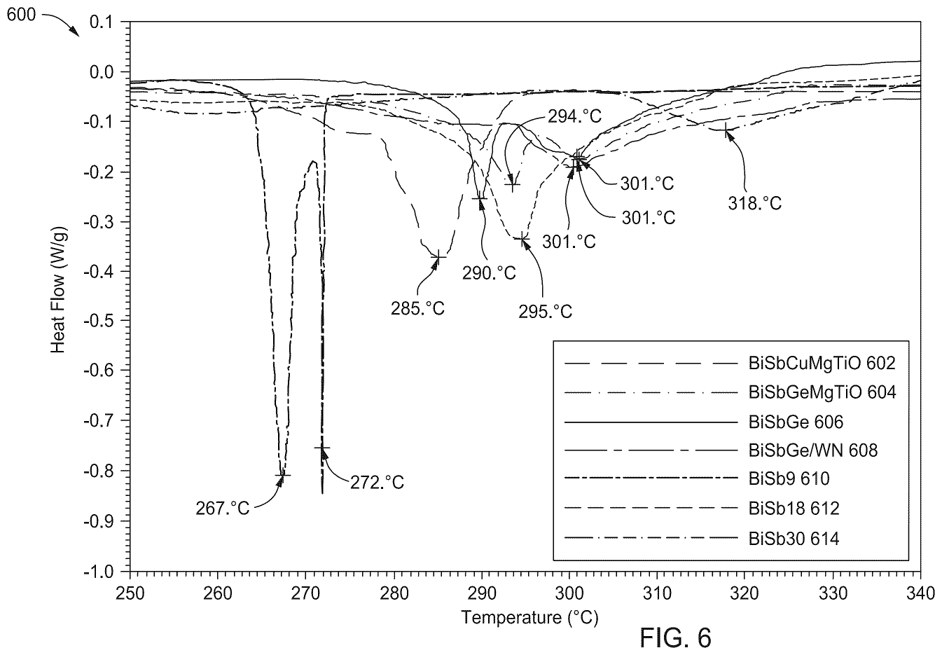

FIG. 6 illustrates a graph 600 of heat flow (Waats per gram w/g) versus temperature in Celsius for various BiSbX layers, according to one embodiment. Each of the various BiSbX layers may be the BiSb layer 310 of any of the SOT devices 300, 350, 400 of FIGS. 3A-4.

In the graph 600, line 602 represents BiSbCuMgTiO, line 604 represents BiSbGeMgTiO, line 606 represents BiSbGe, line 608 represents BiSbGeWN, line 610 represents BiSb with about 9 at. % of Sb, line 612 represents BiSb with about 18 at. % of Sb, and line 614 represents BiSb with about 30 at. % of Sb. The BiSbGeMgTiO, BiSbGeWN, and BiSb doped with about 18 at. % of Sb each have a high melting point, between about 293° C. to about 305° C. BiSb doped with about 30 at. % of Sb has the highest melting point of between about 318° C. and starts to melt around 310° C. The melting point of BiSb doped with GeMgTiO or CuMgTiO is about 30° C. higher than that of undoped BiSb. Thus, doping BiSb with Ge and MgTiO not only decreases the bulk conductivity of BiSb, but further increases the melting point. These two features (reducing bulk conductivity and increasing the melting point of the BiSb layer) help in minimizing shunting and improving thermal reliability when utilized in magnetic sensor applications.

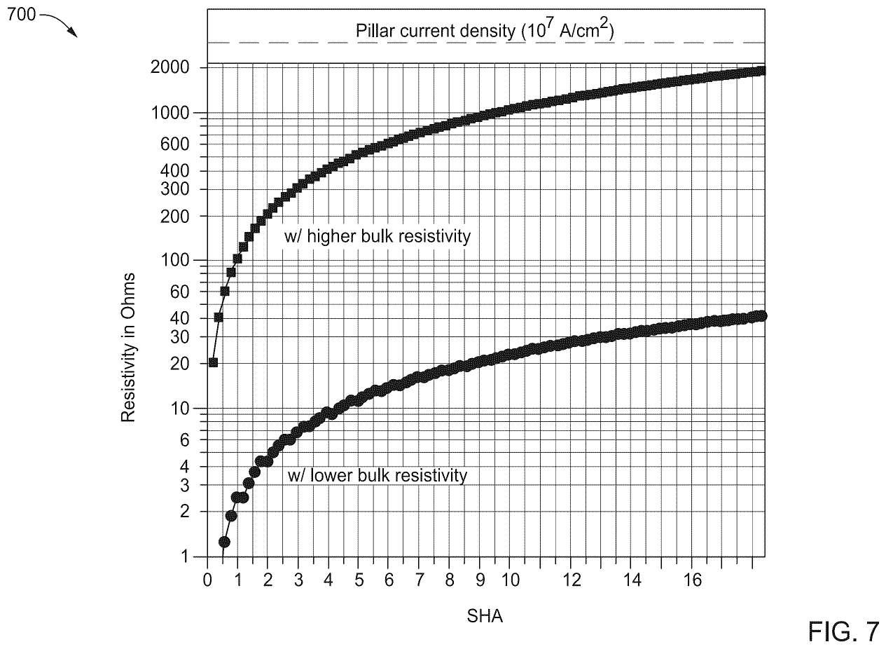

FIG. 7 illustrates a graph 700 of iSHE resistance in ohms of TI layers versus the spin Hall angle (SHA), according to one embodiment. The graph 700 is a signal read out based on the CPP SOT device 400 of FIG. 4A. The TI layers represented in FIG. 7 may be the TI layers 310 of any of the SOT devices 300, 350, 400, 450 of FIGS. 3A-4B. As shown by the graph 700, a higher bulk resistivity (and thus, a lower conductivity) can boost a signal read out (Y axis) to between about 20 ohms to about 2000 ohms, depending on the SHA. On the other hand, a lower bulk resistivity (and thus, a higher conductivity) for a TI layer only results in a signal output of about 1 ohm to about 40 ohms, depending on the SHA.

Therefore, a SOT device comprising a layer of BiSb doped with Ge and MgTiO maintains its surface conductivity while achieving a low bulk conductivity, as the MgTiO increases the band gap energy of BiSbGe layers. Furthermore, BiSb doped with Ge and MgTiO further increases the melting point of BiSb, which minimizes shunting and improves thermal reliability when utilized in magnetic sensor applications. As such, the conductivity of the SOT device can be tuned as needed to produce a desired effect, such as to minimize shunting in a CPP SOT device.

In one embodiment, a SOT device comprises a ferromagnetic layer, and a topological insulating (TI) layer comprising one of: BiSb doped with Ge and MgTiO; BiSb doped with TiO, Z, ZTiO, or ZO, where Z is one of Mg, Be, Ca, Sr, or Ba; BiSb doped with FeCrC; BiSb doped with C; or BiSb doped with X—C or X-O, where X is one or more elements selected from the group consisting of: Sc, Ti, V, Cr, Mn, Fe, Co, Ni, Cu, Zn, Y, Zr, Nb, Mo, Rh, Ag, Ta, Hf, W, Re, Ir, Pt, B, Al, Ga, In, Si, Ge, Sn, P, As, Se, and Te.

The SOT device is a current-perpendicular-to-plane (CPP) SOT device. The TI layer comprises Ge in an amount of 8 at. % or less and MgTiO in an amount of 8 at. % or less, BiSb with about 16 at. % of Sb doped with about 5 at. % Mg or about 8 at. % TiO, or the C or X—C dopant in an amount of about 8 at. % or less. The TI layer has a thickness between about 50 Å to about 600 Å. The SOT device further comprises a buffer layer disposed adjacent to the TI layer, a first interlayer disposed on the TI layer, the first interlayer being disposed between the TI layer and the ferromagnetic layer, and a second interlayer disposed on the ferromagnetic layer. The SOT device further comprises a buffer layer, a second interlayer disposed on the buffer layer, the second interlayer being disposed adjacent to the ferromagnetic layer, and a first interlayer disposed on the ferromagnetic layer, the first interlayer being disposed adjacent to the TI layer. The TI layer comprises one of: BiSb doped with Ge and MgTiO; BiSb doped with TiO, Z, ZTiO, or ZO, where Z is one of Mg, Be, Ca, Sr, or Ba; BiSb doped with FeCrC; or BiSb doped with C. The TI layer comprises BiSb doped with X-C, where X is one or more elements selected from the group consisting of: Sc, Ti, V, Zn, Ta, Hf, W, Re, Ir, Si, and Ge. A magnetic recording device comprises the SOT device.

In another embodiment, a current-perpendicular-to-plane (CPP) SOT device comprises a ferromagnetic layer, and a topological insulating (TI) layer comprising one of: BiSb doped with Ge and MgTiO; BiSb doped with TiO, Z, ZTiO, or ZO, where Z is one of Mg, Be, Ca, Sr, or Ba; BiSb doped with C; or BiSb doped with an X—C dopant or an X—O dopant, where X is one or more elements selected from the group consisting of: Sc, Ti, V, Cr, Mn, Fe, Co, Ni, Cu, Zn, Y, Zr, Nb, Mo, Rh, Ag, Ta, Hf, W, Re, Ir, Pt, B, Al, Ga, In, Si, Ge, Sn, P, As, Se, and Te, wherein the TI layer has a thickness between about 50 Å to about 600 Å.

The TI layer has a melting point between about 293° C. to about 302° C. The TI layer has a conductivity between about 0.2×10⁵ ohm⁻¹ m⁻¹ to about 1.1×10⁵ ohm⁻¹ m⁻¹. The CPP SOT device further comprises a buffer layer, a first interlayer, a second interlayer, and a cap layer. The TI layer is disposed on the buffer layer, the first interlayer is disposed on the TI layer, the ferromagnetic layer is disposed on the first interlayer, the second interlayer is disposed on the ferromagnetic layer, and the cap layer is disposed on the second interlayer. The second interlayer is disposed on the buffer layer, the ferromagnetic layer is disposed on the second interlayer, the first interlayer is disposed on the ferromagnetic layer, the TI layer is disposed on the first interlayer, and the cap layer is disposed on the TI layer. The TI layer comprises one of: BiSb doped with Ge and MgTiO; BiSb doped with TiO, Z, ZTiO, or ZO, where Z is one of Mg, Be, Ca, Sr, or Ba; BiSb doped with FeCrC; or BiSb doped with C. The TI layer comprises BiSb doped with X-C, where X is one or more elements selected from the group consisting of: Sc, Ti, V, Zn, Ta, Hf, W, Re, Ir, Si, and Ge. A magnetic recording device comprises the SOT device.

In yet another embodiment, a current-perpendicular-to-plane (CPP) SOT device comprises a buffer layer, a ferromagnetic layer, a first interlayer, an second interlayer, a cap layer, and a topological insulating (TI) layer comprising one of: BiSb doped with Ge and MgTiO; BiSb doped with TiO, Z, ZTiO, or ZO, where Z is one of Mg, Be, Ca, Sr, or Ba; BiSb doped with C; or BiSb doped with an X—C dopant or an X—O dopant, where X is one or more elements selected from the group consisting of: Sc, Ti, V, Cr, Mn, Fe, Co, Ni, Cu, Zn, Y, Zr, Nb, Mo, Rh, Ag, Ta, Hf, W, Re, Ir, Pt, B, Al, Ga, In, Si, Ge, Sn, P, As, Se, and Te.

The TI layer comprises Ge and MgTiO in an amount of about 8 at. % or less, the X—O dopant in an amount of about 8 at. % or less, or the C or X—C dopant in an amount of about 8 at. % or less. The TI layer has a thickness between about 150 Å to about 600 Å, and wherein the TI layer has a conductivity between about 0.2×10⁵ ohm⁻¹ m⁻¹ to about 1.1×10⁵ ohm⁻¹ m⁻¹. The TI layer is disposed on the buffer layer, the second interlayer is disposed on the TI layer, the ferromagnetic layer is disposed on the second interlayer, and the first interlayer is disposed on the ferromagnetic layer. The first interlayer is disposed on the buffer layer, the ferromagnetic layer is disposed on the first interlayer, and the second interlayer is disposed on the ferromagnetic layer, the TI layer is disposed on the second interlayer. The TI layer comprises one of: BiSb doped with Ge and MgTiO; BiSb doped with TiO, Z, ZTiO, or ZO, where Z is one of Mg, Be, Ca, Sr, or Ba; BiSb doped with FeCrC; or BiSb doped with C. The TI layer comprises BiSb doped with X-C, where X is one or more elements selected from the group consisting of: Sc, Ti, V, Zn, Ta, Hf, W, Re, Ir, Si, and Ge. A magnetic recording device comprises the SOT device.

While the foregoing is directed to embodiments of the present disclosure, other and further embodiments of the disclosure may be devised without departing from the basic scope thereof, and the scope thereof is determined by the claims that follow.

What is claimed is:

1. A spin orbit torque (SOT) device, comprising:
a ferromagnetic layer; and
a topological insulating (TI) layer comprising one of:
BiSb doped with Ge and MgTiO;
BiSb doped with TiO, Z, ZTiO, or ZO, where Z is one of Mg, Be, Ca, Sr, or Ba;
BiSb doped with FeCrC;
BiSb doped with C; or
BiSb doped with X—C or an X-O, where X is one or more elements selected from the group consisting of: Sc, Ti, V, Cr, Mn, Fe, Co, Ni, Cu, Zn, Y, Zr, Nb, Mo, Rh, Ag, Ta, Hf, W, Re, Ir, Pt, B, Al, Ga, In, Si, Ge, Sn, P, As, Se, and Te.

2. The SOT device of claim 1, wherein the SOT device is a current-perpendicular-to-plane (CPP) SOT device.

3. The SOT device of claim 1, wherein the TI layer comprises Ge in an amount of about 8 at. % or less and MgTiO in an amount of about 8 at. % or less, BiSb with about 16 at. % of Sb doped with about 5 at. % Mg or about 8 at. % TiO, or the C or X—C dopant in an amount of about 8 at. % or less.

4. The SOT device of claim 1, wherein the TI layer has a thickness between about 50 Å to about 600 Å.

5. The SOT device of claim 1, further comprising:
a buffer layer disposed adjacent to the TI layer;
a first interlayer disposed on the TI layer, the first interlayer being disposed between the TI layer and the ferromagnetic layer; and
a second interlayer disposed on the ferromagnetic layer.

6. The SOT device of claim 1, further comprising:
a buffer layer;
a second interlayer disposed on the buffer layer, the second interlayer being disposed adjacent to the ferromagnetic layer; and
a first interlayer disposed on the ferromagnetic layer, the first interlayer being disposed adjacent to the TI layer.

7. The SOT device of claim 1, wherein the TI layer comprises one of:
BiSb doped with Ge and MgTiO;
BiSb doped with TiO, Z, ZTiO, or ZO, where Z is one of Mg, Be, Ca, Sr, or Ba;
BiSb doped with FeCrC; or
BiSb doped with C.

8. The SOT device of claim 1, wherein the TI layer comprises BiSb doped with X-C, where X is one or more elements selected from the group consisting of: Sc, Ti, V, Zn, Ta, Hf, W, Re, Ir, Si, and Ge.

9. A magnetic recording device comprising the SOT device of claim 1.

10. A current-perpendicular-to-plane (CPP) spin orbit torque (SOT) device, comprising:
a ferromagnetic layer; and
a topological insulating (TI) layer comprising one of:
BiSb doped with Ge and MgTiO;
BiSb doped with TiO, Z, ZTiO, or ZO, where Z is one of Mg, Be, Ca, Sr, or Ba;
BiSb doped with C; or
BiSb doped with an X—C dopant or an X—O dopant, where X is one or more elements selected from the group consisting of: Sc, Ti, V, Cr, Mn, Fe, Co, Ni, Cu, Zn, Y, Zr, Nb, Mo, Rh, Ag, Ta, Hf, W, Re, Ir, Pt, B, Al, Ga, In, Si, Ge, Sn, P, As, Se, and Te, wherein the TI layer has a thickness between about 50 Å to about 600 Å.

11. The CPP SOT device of claim 10, wherein the TI layer has a melting point between about 293° C. to about 302° C.

12. The CPP SOT device of claim 10, wherein the TI layer has a conductivity between about 0.2×10⁵ ohm⁻¹ m⁻¹ to about 1.1×10⁵ ohm⁻¹ m⁻¹.

13. The CPP SOT device of claim 10, further comprising:
a buffer layer;
a first interlayer;
a second interlayer; and
a cap layer.

14. The CPP SOT device of claim 13, wherein the TI layer is disposed on the buffer layer, the first interlayer is disposed on the TI layer, the ferromagnetic layer is disposed on the first interlayer, the second interlayer is disposed on the ferromagnetic layer, and the cap layer is disposed on the second interlayer.

15. The CPP SOT device of claim 13, wherein the second interlayer is disposed on the buffer layer, the ferromagnetic layer is disposed on the second interlayer, the first interlayer is disposed on the ferromagnetic layer, the TI layer is disposed on the first interlayer, and the cap layer is disposed on the TI layer.

16. The CPP SOT device of claim 10, wherein the TI layer comprises one of:
BiSb doped with Ge and MgTiO;
BiSb doped with TiO, Z, ZTiO, or ZO, where Z is one of Mg, Be, Ca, Sr, or Ba;
BiSb doped with FeCrC; or
BiSb doped with C.

17. The CPP SOT device of claim 10, wherein the TI layer comprises BiSb doped with X-C, where X is one or more elements selected from the group consisting of: Sc, Ti, V, Zn, Ta, Hf, W, Re, Ir, Si, and Ge.

18. A magnetic recording device comprising the CPP SOT device of claim 10.

19. A current-perpendicular-to-plane (CPP) spin orbit torque (SOT) device, comprising:
a buffer layer;
a ferromagnetic layer;
a first interlayer;
a second interlayer; and
a topological insulating (TI) layer comprising one of:
BiSb doped with Ge and MgTiO;
BiSb doped with TiO, Z, ZTiO, or ZO, where Z is one of Mg, Be, Ca, Sr, or Ba;
BiSb doped with C; or
BiSb doped with an X—C dopant or an X—O dopant, where X is one or more elements selected from the group consisting of: Sc, Ti, V, Cr, Mn, Fe, Co, Ni, Cu, Zn, Y, Zr, Nb, Mo, Rh, Ag, Ta, Hf, W, Re, Ir, Pt, B, Al, Ga, In, Si, Ge, Sn, P, As, Se, and Te.

20. The CPP SOT device of claim 19, wherein the TI layer comprises Ge and MgTiO in an amount of about 8 at. % or less, the X—O dopant in an amount of about 8 at. % or less, or the C or X—C dopant in an amount of about 8 at. % or less.

21. The CPP SOT device of claim 19, wherein the TI layer has a thickness between about 150 Å to about 600 Å, and wherein the TI layer has a conductivity between about 0.2×10⁵ ohm⁻¹ m⁻¹ to about 1.1×10⁵ ohm⁻¹ m⁻¹.

22. The CPP SOT device of claim 19, wherein the TI layer is disposed on the buffer layer, the second interlayer is disposed on the TI layer, the ferromagnetic layer is disposed on the second interlayer, and the first interlayer is disposed on the ferromagnetic layer.

23. The CPP SOT device of claim 19, wherein the first interlayer is disposed on the buffer layer, the ferromagnetic layer is disposed on the first interlayer, the second interlayer is disposed on the ferromagnetic layer, and the TI layer is disposed on the second interlayer.

24. The CPP SOT device of claim 19, wherein the TI layer comprises one of:
BiSb doped with Ge and MgTiO;
BiSb doped with TiO, Z, ZTiO, or ZO, where Z is one of Mg, Be, Ca, Sr, or Ba;
BiSb doped with FeCrC; or
BiSb doped with C.

25. The CPP SOT device of claim 19, wherein the TI layer comprises BiSb doped with X-C, where X is one or more elements selected from the group consisting of: Sc, TI, V, Zn, Ta, Hf, W, Re, Ir, Si, and Ge.

26. A magnetic recording device comprising the CPP SOT device of claim 19.
